(19) United States
(12) Patent Application Publication
(10) Pub. No.: US 2024/0409350 A1
(43) Pub. Date: Dec. 12, 2024

(54) VACUUM PROCESSING SYSTEM, APPARATUS AND METHOD FOR TRANSPORTING A THIN FILM SUBSTRATE

(71) Applicants: Frank SCHNAPPENBERGER, Johannesberg (DE); Applied Materials, Inc., Santa Clara, CA (US)

(72) Inventor: Frank SCHNAPPENBERGER, Johannesberg (DE)

(21) Appl. No.: 18/697,050

(22) PCT Filed: Oct. 26, 2021
(86) PCT No.: PCT/EP2021/079646

§ 371 Date: Mar. 29, 2024

(51) Int. Cl. B65H 20/12; B65H 18/10; H01L 31/18

(52) U.S. Cl. CPC B65H 20/12; B65H 18/103; H01L 31/1876

(57) ABSTRACT

An apparatus for transportation of a thin film substrate under vacuum conditions is described. The apparatus for transportation includes a rotatable roller with a substrate facing surface including a first substrate facing surface portion, wherein the substrate facing surface includes one or more gas outlets, wherein the one or more gas outlets are configured for releasing a gas flow and the roller includes a deposition region and at least one non-deposition region. The apparatus further includes a gas distribution for providing the gas flow through the one or more gas outlets into an interspace between the thin film substrate and the first substrate facing surface portion, and a sealing belt conveyor system including one or more sealing belts provided at the at least one non-deposition region.

### FIELD OF INVENTION

Embodiments of the present disclosure relate to apparatuses for transporting a flexible or thin film substrate. Further, embodiments of the disclosure relate to apparatuses, systems and methods for flexible or thin film substrate processing, particularly coating of flexible substrates with thin layers or depositing materials onto thin film or flexible substrates. In particular, embodiments of the disclosure relate to apparatuses employed for transportation of flexible substrates in systems and methods for coating the flexible substrate with a stack of layers, e.g. for thin-film solar cell production, thin-film battery production, or flexible display production.

### BACKGROUND

Processing of flexible substrates, such as plastic films or foils, is in high demand in the packaging industry, semiconductor industries and other industries. Processing may consist of coating a flexible substrate with a material, such as a metal, a semiconductor and a dielectric material, etching and other processing actions conducted on a substrate for the respective applications. Systems performing this task typically include a coating drum, e.g. a cylindrical roller, coupled to a processing system with a roller assembly for transporting the substrate, and on which at least a portion of the substrate is coated.

For example, a coating process such as a CVD process, a PVD process or an evaporation process can be utilized for depositing thin layers onto flexible substrates. Roll-to-roll deposition apparatuses are understood in that a flexible substrate of a considerable length, such as one kilometer or more, is uncoiled from a supply spool, coated with a stack of thin layers, and recoiled again on a wind-up spool. In particular, in the manufacture of thin film batteries, e.g. lithium batteries, the display industry and the photovoltaic (PV) industry, roll-to-roll deposition systems are of high interest. For example, the increasing demand for flexible touch panel elements, flexible displays, and flexible PV modules results in an increasing demand for depositing suitable layers in roll-to-roll-coaters.

For achieving high quality coatings on flexible substrates, various challenges with respect to flexible substrate transportation have to be mastered. For example, providing an appropriate substrate tension as well as a good substrate-roller contact and substrate cooling during the processing of the moving flexible substrate under vacuum conditions remain challenging.

### SUMMARY

In light of the above, an apparatus for transportation of a thin film substrate under vacuum conditions is provided. The apparatus includes a rotatable roller with a substrate facing surface including a first substrate facing surface portion, wherein the substrate facing surface includes one or more gas outlets, wherein the one or more gas outlets are configured for releasing a gas flow; and wherein the roller includes a deposition region and at least one non-deposition region. The apparatus further includes a gas distribution system for providing the gas flow through the one or more gas outlets into an interspace between the thin film substrate and the first substrate facing surface portion; and a sealing belt conveyor system including one or more sealing belts provided at the at least one non-deposition region.

According to an aspect of the present disclosure, a vacuum processing system for depositing a material onto a thin film substrate is provided. The vacuum processing system includes a processing chamber and an apparatus according to embodiments described herein.

According to a further aspect of the present disclosure, a method for transporting a thin film substrate under vacuum conditions is provided. The method includes moving the thin film substrate over a rotatable roller with a substrate facing surface including a first substrate facing surface portion, the roller including a deposition region and at least one non-deposition region; providing a gas flow into an interspace between the thin film substrate and the first substrate facing surface portion; and sealing the interspace between the thin film substrate and the first substrate facing surface portion with one or more sealing belts of a sealing belt conveyor system at the at least one non-deposition region.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the present disclosure are also directed at methods for operating the described apparatus. It includes method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 schematically shows an apparatus according embodiments described herein;

FIG. 2 schematically shows a section of an apparatus according to embodiments described herein;

FIGS. 3A and 3B schematically show a side view and front view of an apparatus according to embodiments described herein;

FIGS. 4A and 4B schematically show a bottom view of an apparatus according to embodiments described herein;

FIG. 5 schematically shows a system according to embodiments described herein; and

FIG. 6 shows a flow diagram of a method according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

Within the following description of the drawings, the same reference numbers refer to the same or similar components. Generally, only the differences with respect to the individual embodiments are described. Unless specified otherwise, the description of a part or aspect in one applies to a corresponding part or aspect in another embodiment as well.

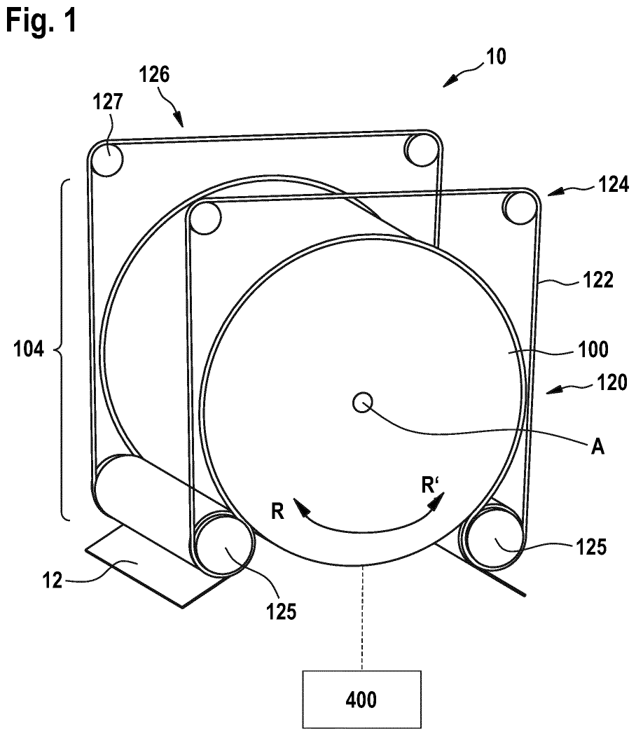

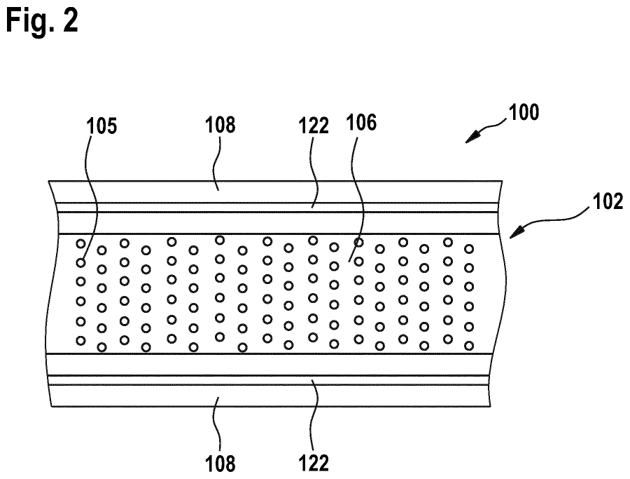

With exemplary reference to FIG. 1, an apparatus 10 for transportation of a thin film substrate 12 is provided. According to embodiments, which can be combined with any other embodiments described herein, the apparatus includes a rotatable roller 100 with a substrate facing surface 102. The substrate facing surface 102 includes a substrate facing surface portion 104. Further, the substrate facing surface 102 includes one or more gas outlets (not shown in FIG. 1). The one or more gas outlets are configured for releasing a gas flow and are further described with respect to FIG. 2. The roller further includes a deposition region and at least one non-deposition region. The apparatus further includes a gas distribution system and a sealing belt conveyor system.

According to embodiments, which can be combined with any other embodiments described herein, the rotatable roller 100 may be rotatable around a central rotation axis A. The roller may be rotated in a rotation direction R and/or R′. The rotatable roller 100 or roller may be configured to transport a thin film or flexible substrate 12.

In the present disclosure, a “flexible substrate” or “thin film substrate” can be understood as a bendable substrate. For instance, the “flexible/thin film substrate” can be a “foil” or a “web”. In the present disclosure the term “flexible substrate”, the term “substrate” and the term “thin film substrate” may be synonymously used. For example, the flexible substrate as described herein may be made of or include materials like PET, HC-PET, PE, PI, PU, TaC, OPP, BOOP, CPP, one or more metals (e.g. copper), paper, combinations thereof, and already coated substrates like Hard Coated PET (e.g. HC-PET, HC-TaC) and the like. In some embodiments, the flexible substrate is a COP substrate provided with an index matched (IM) layer on both sides thereof. For example, the substrate thickness can be 1 μm or more and 1 mm or less, particularly 500 μm or less, or even 200 μm or less. Further particularly, substrates may have a thickness of 4 μm. The substrate width WS can be 0.1 m≤W≤6 m. The substrate may be a transparent or non-transparent substrate. Particularly, the substrate may be a metal foil, e.g. a copper foil.

In the present disclosure, a “rotatable roller” or “roller” can be understood as a drum or a roller having a substrate facing surface 102 for contacting the (flexible) substrate. The expression “substrate facing surface for contacting the flexible substrate” can be understood in that an outer surface of the roller is configured for contacting the flexible substrate during the guiding or transportation of the flexible substrate. Typically, the substrate facing surface is a curved outer surface, particularly a cylindrical outer surface, of the roller. Accordingly, typically the roller is rotatable about the rotation axis and includes a substrate facing surface portion 104. Typically, the substrate facing surface portion 104 is a part of the curved substrate facing surface, e.g. a cylindrically symmetric surface, of the roller. The curved substrate facing surface of the roller may be adapted to be (at least partly) in contact with the flexible substrate during the guiding of the flexible substrate. The substrate facing surface portion may be defined as an angular range of the roller in which the substrate is in contact with the curved substrate facing surface during the guiding of the substrate, and may correspond to the enlacement angle of the roller. For instance, the enlacement angle of the roller may be 90° or more, particularly 180° or more, or even 270° or more. According to some embodiments, which can be combined with other embodiments described herein, the rotatable roller 100 is cylindrical and has a length L of 0.2 m≤L≤8.5 m. Further, the roller may have a diameter D of 0.1 m≤D≤3.0 m. Accordingly, beneficially the roller is configured for guiding and transporting flexible substrates having a large width.

According to embodiments, which can be combined with any other embodiments described herein, the rotatable roller 100 includes a substrate facing surface 102. The substrate facing surface may be seen as a part or region of the drum surface that faces and/or guides the substrate. For example, the substrate facing surface 102 may be understood as a surface of the roller that is adjacent to the substrate or that may contact the substrate. Particularly, the substrate facing surface 102 may be adjacent to a surface of the substrate that is turned away from a surface of the substrate that is coated during a coating or deposition process. The substrate facing surface 102 includes a substrate facing surface portion 104, i.e. a portion of the roller where the substrate is in contact with the substrate facing surface of the roller. Since the substrate is moved via the roller, the substrate facing surface portion 104 may change continuously, i.e. the substrate facing surface portion 104 may correspond to the respective portion of the substrate that is adjacent to the roller or in contact with the roller to a given point in time during transport (by rotation of the roller) of the substrate.

According to embodiments, which can be combined with any other embodiments described herein, the apparatus 10 includes a gas distribution system 400 for providing the gas flow through the one or more gas outlets into an interspace between the thin film substrate 12 and the first substrate facing surface portion 104. The gas distribution system 400 is exemplarily shown in FIG. 1 to be a system connected to the roller. The person skilled in the art may understand that the gas distribution system may also be provided (at least partly) within the roller. Generally, the gas distribution system may be connected to the roller and may supply a gas flow through the one or more gas outlets arranged in the surface of the roller. Inside the roller, gas supply channels may be provided. The gas supply channels may be connected to the one or more gas outlets. Particularly, the gas flow may be provided at the substrate facing surface portion 104, i.e. the gas flow may be supplied through the one or more gas outlets where the substrate may contact the substrate facing surface 102. A distance between the substrate and the substrate facing surface of the roller, i.e. a dimension of the interspace between the substrate and the substrate facing surface 102, may vary according to the pressure with which the gas flow may be provided towards the substrate.

Advantageously, the gas flow may be provided for preventing the substrate from directly contacting the rotatable roller 100. The gas flow may further be provided for cooling the substrate transported via the roller. Accordingly, when high deposition temperatures are applied to the substrate during deposition, the gas flow may prevent or avoid damage of the substrate. For example, the rotatable roller 100 may be cooled to temperatures of between 0 and −10° C., particularly to temperatures of −11° C. to −15° C., more particularly to temperatures of −16° C. to −20° C. to provide for sufficient cooling of the transported substrate. For example, the deposition material may be provided with a temperature of 280° C. to 290° C. towards the substrate. Accordingly, cooling of the rotatable roller may be configured such that the temperature of the deposition material decreases below the deposition materials melting point. Further accordingly, the deposited material made thus, remains at the substrate.

According to embodiments, which can be combined with any other embodiments described herein, the gas flow may include a cooling gas. The cooling gas may be an inert gas. The cooling gas may be selected of the group consisting of helium (H₂), argon (Ar), carbon dioxide (CO₂) and/or combinations thereof. According to embodiments, the gas flow may be provided with a pressure P_{g}. The pressure P_{g} may be from 0 to 100 mbar, particularly from 1 to 10 mbar. According to embodiments, a gas volume provided by the gas flow to the substrate facing surface or the substrate facing surface portion may be from 0.1 cm³ and 500 cm³, particularly from 1 to 100 cm³, more particularly from 2 to 10 cm³.

According to embodiments, which can be combined with any other embodiments described herein, the apparatus includes a sealing belt conveyor system. The sealing belt conveyor system 120 includes one or more sealing belts 122 and is provided at the at least one non-deposition region. The sealing belt conveyor system 120 may be configured to provide the one or more sealing belts 122 at the first substrate facing surface portion 104. Further, the sealing belt conveyor system may be configured to press the substrate against the rotatable roller 100, i.e. against the at least one non-deposition region 108. Particularly, the one or more sealing belts 122 may be pressed against the rotatable roller 100. Further particularly, the one or more sealing belts 122 may be provided at the at least one non-deposition region 108 of the rotatable roller 100. According to embodiments, the one or more sealing belts 122 may be configured to seal the interspace between the thin film substrate 12 and the first substrate facing surface portion 104. Accordingly, the sealing belt conveyor system 120 may be configured to prevent cooling gas from escaping from the interspace.

Advantageously, by providing a pressure via the sealing belts towards the roller at the ends of the roller, the substrate can be fixedly transported on the roller. Thus, the gas flow provided for cooling the substrate may not or only partially escape at the sides of the roller and out of the interspace between the substrate and the roller. Thus, excessive floating of the substrate can be prevented or avoided. Accordingly, the substrate can remain flat on the rotatable roller and material deposition onto the substrate is more uniform. The formation of wrinkles or folds on the thin film substrate can be avoided or prevented. Therefore, yield of substrate processing can be increased. Further advantageously, less gas can escape into the vacuum chamber. Thus, maintenance of vacuum conditions can be facilitated. Accordingly, the deposition process can be more efficient and less energy consuming since devices for providing the vacuum in the processing chamber, e.g. pumps, have to be used less frequently.

According to embodiments, which can be combined with any other embodiments described herein and with exemplary reference to FIG. 2, the rotatable roller 100 includes a deposition region 106 and at least one non-deposition region 108. The deposition region 106 may be understood as a part of the roller that corresponds to a region of the substrate where coating or deposition material may reach the substrate during coating or deposition. Particularly, the deposition region 106 may be a part of the substrate facing surface 102 or the substrate facing surface portion 104 of the cylindrical roller that extends about ⅔, particularly ¾, more particularly ⅘, even more particularly ⅚ along a length of the roller. In contrast thereto, the non-deposition region 108 may be understood as a part of the roller that corresponds to a region of the substrate where no coating or deposition material may reach the substrate during coating or deposition. Particularly, the non-deposition region 108 may be a part of the substrate facing surface 102 or the substrate facing surface portion 104 of the cylindrical roller that extends about ⅓, particularly ¼, more particularly ⅕, even more particularly ⅙ along the length of the roller. Particularly, the rotatable roller 100 may include two non-deposition regions at axially opposing ends of the length of the roller. In other words, the rotatable roller may include two non-deposition regions at two opposing sides of the central axis of the roller. The non-deposition region 108 may be arranged at an outermost side of the roller of the length of the roller.

According to embodiments that can be combined with any other embodiment described herein, the rotatable roller may include two non-deposition regions at axially opposing ends of the rotatable roller 100, i.e. at axially opposing ends of the length of the roller or of the central axis A of the roller. At each of the axially opposing ends, one sealing belt of the one or more sealing belts 122 may be provided. Accordingly, the substrate may be pressed against the rotatable roller 100 at axially opposing ends of the roller. In other words, the sealing belt conveyor system 120 may be configured to press the thin film substrate against the at least one non-deposition region 108, particularly the two non-deposition regions at axially opposing ends of the roller, with a predetermined force. The predetermined force may be a pressure P_{pd} of 1 mbar to 2000 mbar, particularly of 10 to 500 mbar. Additionally or alternatively, the one or more sealing belts may be provided with a tension. The tension of the one or more sealing belts may be from 1 to 500 N, particularly from 10 to 200 N.

According to embodiments that can be combined with any other embodiment described herein, the one or more sealing belts 122 may be made of a flexible and/or bendable material suitable for use in a thermally challenged environment. Furthermore, the one or more sealing belts 122 may be made of a material suitable for the use in a vacuum environment. For example, the one or more sealing belts 122 may be made from any kind of plastics, particularly thermosetting polymers; metals, like e.g. alumina; rubber; polyurethane; polychloroprene compound reinforced with aramid fibers; vanadium steel; PET; polyamide; polychloroprene; polyester and/or combinations thereof. The one or more sealing belts may have a thickness of 0.01 to 5 cm, particularly 0.05. to 2 cm, more particularly 0.1 to 1 cm.

According to embodiments, which can be combined with any other embodiments described herein and exemplarily referring back to FIG. 1, the sealing belt conveyor system 120 may include a first sealing belt transportation track 124 and a second sealing belt transportation track 126. The first sealing belt transportation track 124 and the second sealing belt transportation track 126 may be provided at the two non-deposition regions 108. Accordingly, the first sealing belt transportation track 124 and the second sealing belt transportation track 126 may be provided at the axially opposing ends of the rotatable roller 100. According to embodiments, the sealing belt conveyor system may include two sealing belts 122, wherein one of the two sealing belts 122 may be provided at the first sealing belt transportation track 124 and wherein the other of the two sealing belts 122 may be provided at the second sealing belt transportation track 126. The first sealing belt transportation track 124 and the second sealing belt transportation track 126 may be arranged at axially opposing ends of the central axis or of the length of the roller. In other words, the first sealing belt transportation track 124 and the second sealing belt transportation track 126 may oppose each other at the ends of the roller separated by the length of the roller.

Advantageously, the one or more sealing belts may not interfere with the deposition process as the one or more sealing belts are provided outside the area where deposition material may reach the substrate. Accordingly, the one or more sealing belts may beneficially keep the substrate at the roller to improve deposition while not or only little being affected by the deposition process.

According to embodiments, which can be combined with any other embodiments described herein, the sealing belt conveyor system 120 may include one or more first rolls 125 and/or one or more second rolls 127. The one or more first rolls 125 may have a larger diameter than the one or more second rolls 127. The one or more first rolls 125 may be configured to keep the substrate and/or the one or more sealing belts at the roller. The one or more first rolls may be configured to press the substrate against the roller, i.e. the one or more first rolls may be configured to provide additional sealing between the roller and the substrate. In other words, the one or more first rolls may be configured to provide additional sealing between the substrate and the substrate facing surface of the roller. The one or more first rolls may be configured to guide the one or more sealing belts and the substrate.

According to embodiments, which can be combined with any other embodiments described herein, the apparatus may include two first rolls wherein one first roll may be arranged at a first side of the roller and another first roll may be arranged at a second side of the roller. The first and second side of the roller may be the respective sides whereat the substrate is transported. The two first rolls may include axes that are parallel to the central axis of the roller as can be seen in FIG. 1. Accordingly, each of the one or more first rolls may have axially opposing ends that are adjacent to the axially opposing ends of the roller. A first sealing belt of the one or more sealing belts may be spanned between the two first rolls at one end of the two first rolls and a second sealing belt of the one or more sealing belts may be spanned between the two first rolls at an opposing end of the two first rolls. The one or more first rolls may include guiding sections where the first sealing belt and the second sealing belts fit in size, i.e. fit by width of the one or more sealing belts 122 for ease of guidance along the one or more first rolls and the rotatable roller 100.

According to embodiments, which can be combined with any other embodiments described herein, the one or more second rolls 127 may be configured to support guiding of the one or more sealing belts 122. For example, as exemplarily seen in FIG. 1, the one or more second rolls 127 may be arranged above the one or more first rolls 125. The one or more second rolls may be arranged such that the predetermined pressure can be provided to the substrate. The position of the one or more second rolls and a total length of the one or more sealing belts may be chosen such that the sealing belt conveyor system or the one or more sealing belts may provide the predetermined pressure to the substrate.

According to embodiments, which can be combined with any other embodiments described herein, the sealing belt conveyor system 120 may include an actuator for moving the one or more sealing belts with the roller. Alternatively, the one or more sealing belts may be moved by a movement of the roller, i.e. no external actuator may be provided with the sealing belt conveyor system. The one or more sealing belts may be moved in the rotation direction of the roller. The one or more sealing belts may be moved with a speed similar to a rotation speed of the roller.

According to embodiments, which can be combined with any other embodiments described herein and exemplarily referring back to FIG. 2, the rotatable roller 100 includes a substrate facing surface 102. The substrate facing surface may include one or more gas outlets 105. The one or more gas outlets 105 may be configured for releasing a gas flow. The gas flow may be provided by the gas distribution system. The one or more outlets may be distributed over the substrate facing surface. The one or more gas outlets may be arranged in a pattern and/or may be randomly distributed throughout the substrate facing surface 102. Particularly, the one or more gas outlets may be provided within the deposition region 106 of the roller. According to embodiments, any individual gas outlet, any subgroup of the gas outlets or all gas outlets can be selected from the group consisting of: openings, holes, slits, nozzles, blast pipes, spray valves, duct openings, orifices, jets, outlets provided by a porous material and the like. For example, the substrate facing surface may include a porous layer, i.e. a layer including the porous material. The porous layer may be configured to release the gas flow. Particularly, a similar amount or volume of gas can be released irrespective of the gas outlet provided. As shown in FIG. 2, the one or more sealing belts 122 may be provided at the at least one non-deposition region 108, in the example of FIG. 2 at two non-deposition regions at axially opposing ends, of the roller. It is to be understood that the substrate is omitted in FIG. 2.

According to embodiments, which can be combined with any other embodiments described herein, the substrate facing surface may include a gas outlet density of 1 to 10 gas outlets per cm² of the substrate facing surface. In other words, the number of gas outlets per cm² of the substrate facing surface may be at least 1 to 20, more particularly 1 to 5. The one or more gas outlets may have a diameter of 5 to 200 μm, more particularly 10 to 100 μm.

According to embodiments, which can be combined with any other embodiments described herein, the one or more gas outlets may be closable. Accordingly, when the substrate facing surface 102 is free from a substrate, i.e. when no substrate is currently transported at the substrate facing surface, the one or more gas outlets may be closed. For example, the one or more gas outlets may include a closure that closes the one or more gas outlets according to a rotation position of the roller. Each of the one or more gas outlets may include a closure. The closure may be selected from a flap, a sealing and the like. Closing of the one or more gas outlets may be regulated automatically, particularly according to the rotation position of the rotatable roller 100. Accordingly, the gas flow may be provided when the substrate is in contact with or guided by the substrate facing surface portion.

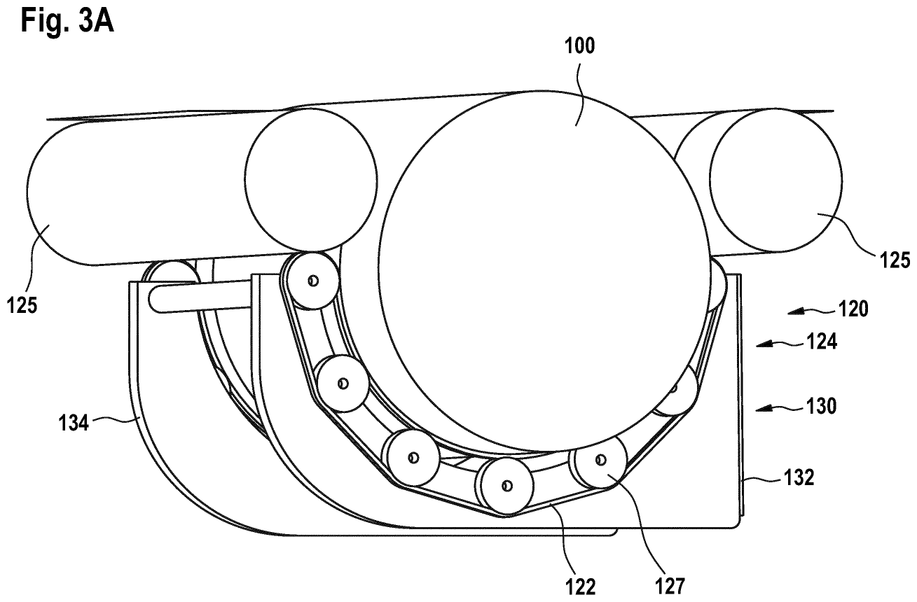

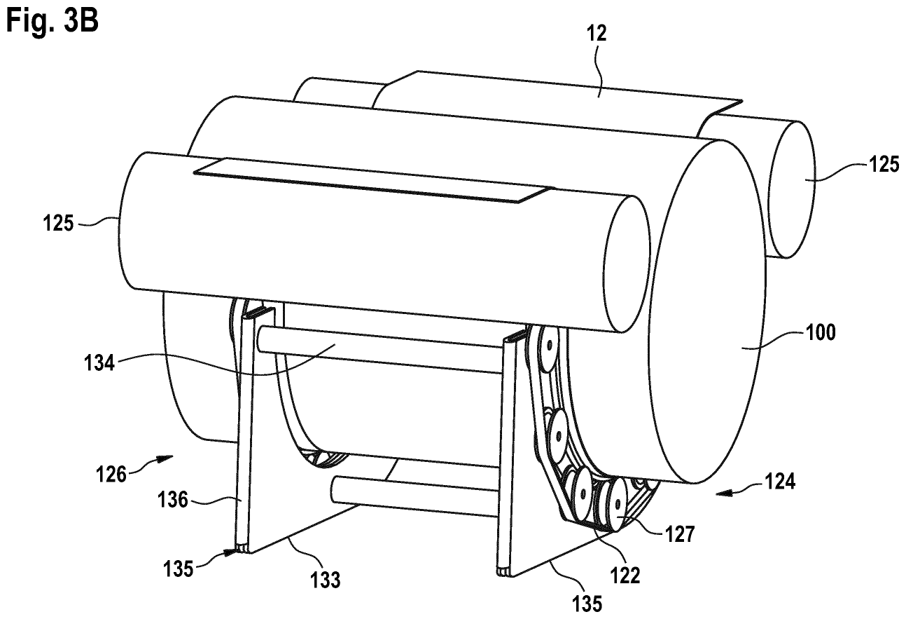

According to embodiments, which can be combined with any other embodiments described herein and with exemplary reference to FIGS. 3A and 3B, the apparatus 10 may include a support 130. The support 130 may be arranged above, below and/or sideways of the roller. Particularly, the support 130 may be arranged vertically below the rotatable roller 100. The first sealing belt transportation track 124 and the second sealing belt transportation track 126 may be arranged at the support 130. Particularly, the support 130 may include a first support wall 132 and a second support wall 134. The first and second support walls 132, 134 may be arranged at the two axially opposing ends of the central axis of the rotatable roller 100. An extension in length of the first support wall 132 and the second support wall 134 may be in a direction different from the central axis of the roller. The first sealing belt transportation track 124 and the second sealing belt transportation track 126 may be provided at the first support wall 132 and the second support wall 134, respectively. The one or more first rolls 125 may be arranged above the support. The support may carry the one or more first rolls. According to embodiments, the one or more first rolls 125 and the one or more second rolls 127 may be in contact with each other. Accordingly, a drive force for moving the one or more first rolls and the one or more second rolls may be transferred.

According to embodiments, which can be combined with any other embodiments described herein, the support 130 may include one or more spacers 134. The one or more spacers may include a length corresponding to a width of the deposition region 106 of the roller and may be arranged between the first and second support walls 132, 134. The spacers may extend substantially parallel to the central axis of the roller. The spacers may support the first and second support walls 132, 134 of the support 130. The one or more spacers may be arranged such that deposition of material onto the substrate at the deposition portion 106 of the roller is possible.

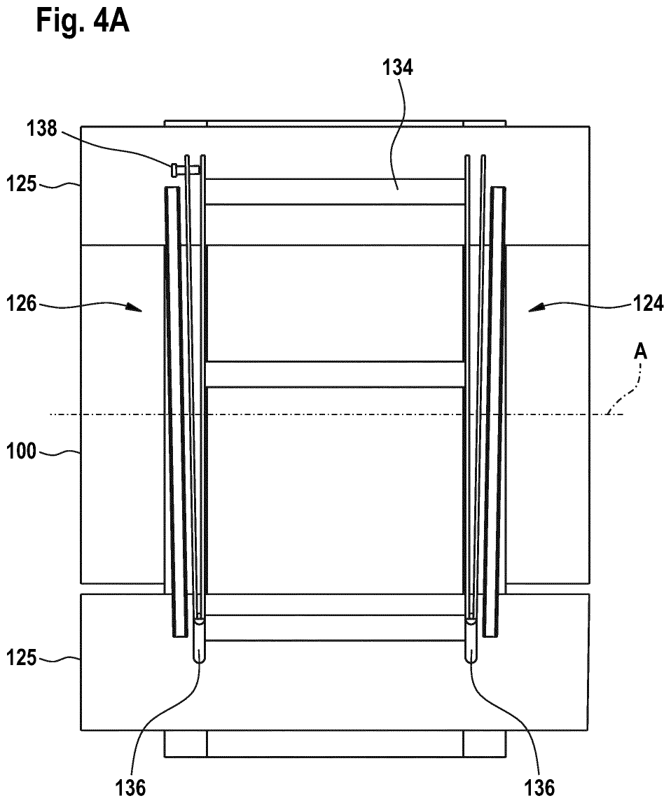

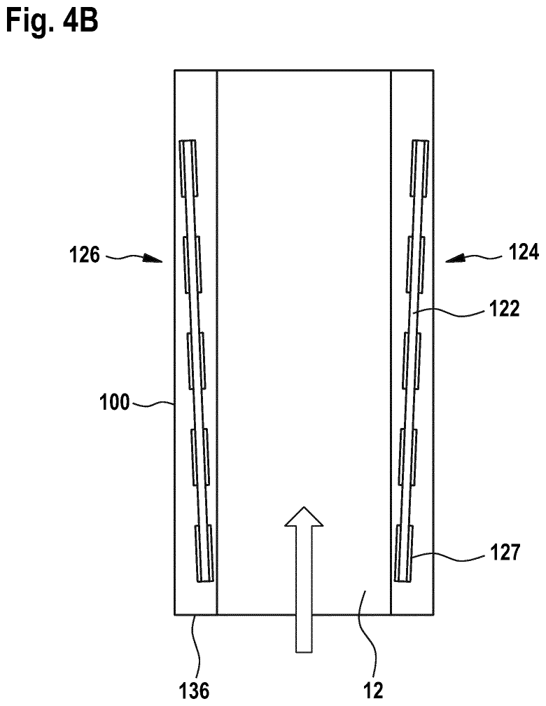

According to embodiments, which can be combined with any other embodiments described herein and with exemplary reference to FIGS. 4A and 4B, each of the first and second support walls 132, 134 may include a first wall portion 133 and a second wall portion 135. Further, the first and second support walls 132, 134 may include a hinge 136. The hinge may be configured to alter an angle α between the first wall portion 133 and the second wall portion 135. The first wall portion 133 and the second wall portion 135 may be parallel to each other. The hinge 136 may connect the first wall portion 133 and the second wall portion 135 at one end of the first wall portion 133 and the second wall portion 135. The first wall portion 133 and/or the second wall portion 135 may include an adjuster 138 such as an adjustment screw, a forcing screw and the like. The adjuster 138 may be configured to alter the angle α between the first wall portion and the second wall portion.

According to embodiments, which can be combined with any other embodiments described herein, the first wall portion 133 may be stationary and the second wall portion 135 may be movable. The hinge 136 may allow for a movement of the second wall portion 135. The adjuster 138 may alter a position of the second wall portion. For example, by adjusting the adjuster, the angle α may be altered to move the first wall portion and the second wall portion away from or towards each other. For example, the angle α can be between 0° and 10°, particularly between 0.5° and 7°, more particularly between 1° and 5°. The angle may open in a direction of rotation indicated by the white arrow in FIG. 4B.

Advantageously, providing an angle between the first wall portion and the second wall portion, i.e. distancing the first wall portion and the second wall portion, may result in pulling the substrate in opposing directions such that wrinkles or folds can be prevented. In other words, a tension to tighten the substrate may be provided by altering the angle between the first wall portion and the second wall portion. Thus, the substrate is straightened and deposition quality is improved. Thus, a more smooth and uniform deposition onto the substrate can be provided. Further, deposition efficiency can be improved.

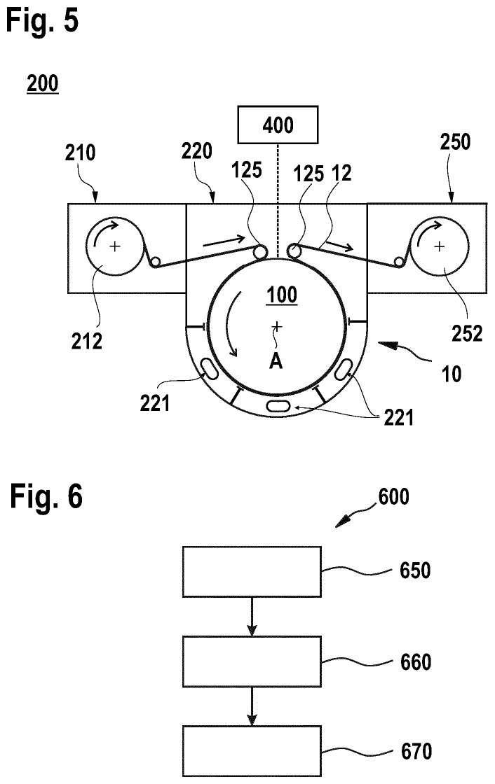

With exemplary reference to FIG. 5, a vacuum processing system 200 according to the present disclosure is described. According to embodiments, which can be combined with any other embodiments described herein, the vacuum processing system 200 includes a processing chamber 220 including a plurality of processing units 221. The plurality of processing units 221 includes at least one deposition unit. Further, the vacuum processing system 200 includes an apparatus for transportation including a rotatable roller 100 according to any embodiments described herein for guiding the substrate past the plurality of processing units 221. As schematically shown in FIG. 1, the rotatable roller 100 is connected to a gas distribution system 400. Typically, the gas distribution system 400 is configured for supplying a cooling gas to the rotatable roller 100, such that the cooling gas can be provided to the flexible substrate through the plurality of gas outlets 105 as described herein.

According to embodiments, which can be combined with any other embodiments described herein and as exemplarily shown in FIG. 5, typically the vacuum processing system 200 is a roll-to-roll processing system. The rotatable roller 100 according to any embodiments described herein can be a processing drum or coating drum of the vacuum processing system. According to embodiments, which can be combined with any other embodiments described herein, the vacuum processing system 200 includes a first spool chamber 210 housing a storage spool 212 for providing the flexible substrate 12.

Additionally, the vacuum processing system 200 includes the processing chamber 220 arranged downstream from the first spool chamber 210. Typically, the processing chamber 220 is a vacuum chamber and includes the plurality of processing units 221. The plurality of processing units 221 include at least one deposition unit. Accordingly, in the present disclosure, a “processing chamber” can be understood as a chamber having at least one deposition unit for depositing material on a substrate. Accordingly, the processing chamber may also be referred to as a deposition chamber. The term “vacuum”, as used herein, can be understood in the sense of a technical vacuum having a vacuum pressure of less than, for example, 10 mbar. Typically, the pressure in a vacuum chamber as described herein may be between 10⁻⁵ mbar and about 10⁻⁸ mbar, more typically between 10⁻⁵ mbar and 10⁻⁷ mbar, and even more typically between about 10⁻⁶ mbar and about 10⁻⁷ mbar.

As exemplarily shown in FIG. 5, the plurality of processing units may be arranged in a circumferential direction around the rotatable roller 100. As the roller rotates, the flexible substrate 12 is guided past the processing units which face toward the substrate facing surface of the roller, so that the surface of the flexible substrate can be processed while being moved past the processing units at a predetermined speed. For example, the plurality of processing units may include one or more units selected from the group consisting of: a deposition unit, an etching unit, and a heating unit. A deposition unit of the vacuum processing system as described herein can be a sputter deposition unit, e.g. an AC (alternating current) sputter source or a DC (direct current) sputter source, a RF (radio frequency) sputter source, a MF (middle frequency) sputter source, a pulsed sputter source, a pulsed DC sputter source, a magnetron sputter source, a reactive sputter source, a CVD deposition unit, a PECVD deposition unit, a PVD deposition unit or another suitable deposition unit. It is to be understood that typically a deposition unit as described herein is adapted for depositing a thin film on a flexible substrate, e.g., to form a flexible display device, a touch-screen device component, or other electronic or optical devices. A deposition unit as described herein can be configured for depositing at least one material selected from the group of conductive materials, semi-conductive materials, dielectric materials, or isolating materials.

Additionally, as exemplarily shown in FIG. 5, the vacuum processing system 200 may include a second spool chamber 250 arranged downstream from the processing chamber 220. The second spool chamber 250 houses a wind-up spool 252 for winding the flexible substrate 12 thereon after processing.

According to embodiments, which can be combined with any other embodiments described herein, the vacuum processing system 200 may include a shield for shielding the one or more sealing belts from deposition material. Advantageously, and in addition to the one or more sealing belts being provided at the non-deposition region of the roller, the one or more sealing belts may be shielded from deposition material. Accordingly, thermal load towards the one or more sealing belts may be reduced or avoided. For example, the shield may be arranged at a chamber wall of the processing chamber. The shield may further be arranged at the support 130. The vacuum processing system may include more than one shield.

According to embodiments, which can be combined with any other embodiments described herein, the vacuum processing system 200 may include a controller. The controller may be configured to issue commands for regulating a first speed of the rotatable roller 100 and a second speed of the one or more sealing belts 122. The first speed and the second speed may be synchronized such that the substrate and the one or more sealing belts are moved at a similar speed.

According to embodiments, which can be combined with any other embodiments described herein and with exemplary reference to the block diagram shown in FIG. 6, a method 600 for transporting a thin film substrate 12 under vacuum conditions is provided. The method includes moving (represented by block 650 in FIG. 6) the thin film substrate over a rotatable roller 100 with a substrate facing surface 102 including a substrate facing surface portion 104. The roller includes a deposition region 106 and at least one non-deposition region 108. Further, the method includes providing (represented by block 660 in FIG. 6) a gas flow into an interspace between the thin film substrate 12 and the substrate facing surface portion 104 and sealing (represented by block 670 in FIG. 6) the interspace between the thin film substrate 12 and the substrate facing surface portion 104 with one or more sealing belts 122 of a sealing belt conveyor system 120 at the at least one non-deposition region 108.

In view of the above, it is to be understood that compared to the state of the art, embodiments as described herein provide for improved flexible or thin film substrate transportation, improved cooling of the flexible substrate during substrate processing such that better processing results, e.g. higher coating or deposition quality can be obtained.

While the foregoing is directed to embodiments of the disclosure, other and further embodiments of the disclosure may be devised without departing from the basic scope thereof, and the scope thereof is determined by the claims that follow.

1. An apparatus for transportation of a thin film substrate under vacuum conditions, the apparatus comprising:
a rotatable roller with a substrate facing surface comprising a first substrate facing surface portion, wherein:
the substrate facing surface comprises one or more gas outlets, the one or more gas outlets being configured for releasing a gas flow; and
the roller comprises a deposition region and at least one non-deposition region;
a gas distribution system for providing the gas flow through the one or more gas outlets into an interspace between the thin film substrate and the first substrate facing surface portion; and
a sealing belt conveyor system comprising one or more sealing belts provided at the at least one non-deposition region.

2. The apparatus according to claim 1, wherein the one or more sealing belts are configured to seal the interspace between the thin film substrate and the first substrate facing surface portion.

3. The apparatus according to claim 1, wherein the sealing belt conveyor system is configured to provide the one or more sealing belts at the first substrate facing surface portion and to press the thin film substrate against the rotatable roller.

4. The apparatus according to claim 1, wherein the sealing belt conveyor system is configured to press the thin film substrate against the at least one non-deposition region with a predetermined force.

5. The apparatus according to claim 1, wherein the roller comprises two non-deposition regions at two opposing sides of a central axis (A) of the roller, wherein the sealing belt conveyor system comprises a first sealing belt transportation track and a second sealing belt transportation track, the first sealing belt transportation track and the second sealing belt transportation track being provided at the two non-deposition regions.

6. The apparatus according to claim 5, wherein the sealing belt conveyor system comprises two sealing belts, wherein one of the two sealing belts is provided at the first sealing belt transportation track and the other of the two sealing belts is provided at the second sealing belt transportation track.

7. The apparatus according to claim 1, wherein the sealing belt conveyor system comprises at least one of one or more first rolls and one or more second rolls.

8. The apparatus according to claim 7, wherein the first sealing belt transportation track and the second sealing belt transportation track comprise the one or more second rolls.

9. The apparatus according to claim 7, wherein the one or more first rolls have a larger diameter than the one or more second rolls, and wherein the one or more first rolls are configured for guiding the sealing belt and the thin film substrate.

10. The apparatus according to claim 1, wherein the sealing belt conveyor system comprises a support, wherein the support is arranged vertically below the roller.

11. The apparatus according to claim 10, wherein the support comprises a first support wall and a second support wall, the first and second support walls being arranged at the two opposing sides of the central axis (A) of the roller.

12. The apparatus according to claim 11, wherein the support comprises one or more spacers, the spacers comprising a length corresponding to a width of the deposition region of the roller and being arranged between the first and second support walls.

13. The apparatus according to claim 11, wherein each of the first and second support walls comprises a first wall portion and a second wall portion.

14. The apparatus according to claim 13, wherein the first wall portion is stationary and the second wall portion is movable.

15. The apparatus according to claim 13, wherein the one or more second rolls are arranged at the second wall portion.

16. The apparatus according to claim 1, wherein the sealing belt conveyor system comprises an actuator for moving the one or more sealing belts.

17. A vacuum processing system for depositing a material onto a thin film substrate, the vacuum processing system comprising:
a processing chamber; and
an apparatus according to claim 1.

18. The vacuum processing system according to claim 17 further comprising a controller, the controller being configured to issue commands to regulate a first speed of the roller and a second speed of the one or more sealing belts.

19. A method for transporting a thin film substrate under vacuum conditions, the method comprising:
moving the thin film substrate over a rotatable roller with a substrate facing surface comprising a first substrate facing surface portion, the roller comprising a deposition region and at least one non-deposition region;
providing a gas flow into an interspace between the thin film substrate and the first substrate facing surface portion; and
sealing the interspace between the thin film substrate and the first substrate facing surface portion with one or more sealing belts of a sealing belt conveyor system at the at least one non-deposition region.

20. The apparatus according to claim 13, wherein the first and second support walls each comprises a hinge, the hinge being configured to alter an angle (α) between the first wall portion and the second wall portion.
